(19) United States
(12) Patent Application Publication
(10) Pub. No.: US 2014/0124475 A1
(43) Pub. Date: May 8, 2014

(54) METHOD OF MANUFACTURING PRINTED CIRCUIT BOARD

(71) Applicant: SAMSUNG ELECTRO-MECHANICS CO., LTD., Suwon (KR)

(72) Inventor: Yang Je LEE, Busan (KR)

(73) Assignee: SAMSUNG ELECTRO-MECHANICS CO., LTD., Suwon (KR)

(21) Appl. No.: 13/827,241

(22) Filed: Mar. 14, 2013

(30) Foreign Application Priority Data
Nov. 5, 2012 (KR) 10-2012-0124139

(51) Int. Cl. H05K 3/00

(52) U.S. Cl. CPC H05K 3/0097
USPC 216/18

(57) ABSTRACT

The present invention relates to a method of manufacturing a printed circuit board. The method of manufacturing a printed circuit board including: preparing two copper clad laminates, each consisting of an insulating layer and copper foil layers laminated on upper and lower surfaces of the insulating layer; bonding the two copper clad laminates after disposing the lower copper foil layers of the copper clad laminates to face each other; processing a via hole passing through the upper copper foil layer and the insulating layer of each copper clad laminate; fill-plating a via electrode inside the via hole and forming a circuit layer on an outer layer of the copper clad laminate; separating the bonded copper clad laminates; and patterning the lower copper foil layer of the separated copper clad laminate is provided.

### CROSS-REFERENCE TO RELATED APPLICATIONS

Claim and incorporate by reference domestic priority application and foreign priority application as follows:

“Cross Reference to Related Application This application claims the benefit under 35 U.S.C. Section 119 of Korean Patent Application Serial No. 10-2012-0124139, entitled filed Nov. 5, 2012, which is hereby incorporated by reference in its entirety into this application.”

### BACKGROUND OF THE INVENTION

1. Field of the Invention

The present invention relates to a method of manufacturing a printed circuit board, and more particularly, to a method of manufacturing a printed circuit board using two copper clad laminates.

2. Description of the Related Art

A printed circuit board (PCB) is used in component mounting and wiring of electronic devices and manufactured by attaching a thin plate made of copper or the like to one surface of a phenol resin insulation board or an epoxy resin insulation board, performing etching along a wiring pattern of a circuit (removing through corrosion while leaving only a circuit on a line) to form a necessary circuit, and boring hole for attaching and mounting components.

PCBs are classified into a single-sided PCB with wirings formed only on one surface of an insulating substrate, a double-sided PCB with wirings formed on both surfaces, and a multi-layered board (MLB) with wirings formed on a plurality of layers.

In the past, since component elements and circuit patterns were simple, single-sided PCBs were used, but recently, as the complexity of circuits and the demand for densification and miniaturization of the circuits are increased, double-sided PCBs or MLBs are mainly used.

A method of manufacturing a PCB will be described below.

First, generally, the step of processing a plated through hole (PTH) in a copper clad laminate (CCL) is performed. Next, the step of plating the CCL having the PTH with copper and filling the PTH is performed. Next, the exposure step of forming a circuit image by laminating a dry film (DF) on the copper-plated CCL, disposing an artwork film (not shown) on the laminated DF, and irradiating an ultraviolet (UV) ray is performed. Next, the development step of removing a portion uncured in the exposure step (a portion in which light is not received) using a developing solution is performed, and the etching step of removing a portion in which the DF is not left from the copper-plated portion on an insulator using an etching solution is performed. Next, a finally completed PCB is obtained by performing the step of removing the DF, which serves as a protection film during etching, using a stripping solution. Otherwise, an MLB having multiple layers of circuit layers is obtained by applying an insulating layer again on the finally completed PCB and repeatedly performing the above process.

However, the above process is a process for manufacturing a single completed PCB. In order to increase a process yield, a manufacturing method of obtaining two PCBs through a single process by building-up circuit layers on both surfaces of an insulating layer and cutting a middle part of the insulating layer is provided (Korean Patent Laid-open Publication No. 10-2009-0093673, 10-2010-0081525). However, there is no separate circuit layer on the separated surface of the insulating layer and thus a process of forming a circuit layer on the separated surface should be performed again.

In Korean Patent Laid-open Publication No. 10-2010-0110459, in order to overcome this problem, a method of forming circuit layers on upper and lower surfaces of a coreless carrier, performing a build-up process to sequentially form an insulating layer and a secondary circuit layer, and finally separating only the coreless carrier is provided.

However, since this method should perform a build-up process several times as described above, a process becomes complicated, thus causing deterioration of productivity.

Further, since the circuit layers should be formed on the upper and lower surfaces of the coreless carrier first, the coreless carrier is positively necessary, ultimately increasing manufacturing costs.

Further, since a printed circuit board after the build-up process should be separated from the coreless carrier, process steps are increased.

### RELATED ART DOCUMENT

### Patent Document

Patent Document 1: Korean Patent Laid-open Publication No. 10-2009-0093673

Patent Document 2: Korean Patent Laid-open Publication No. 10-2010-0081525

Patent Document 3: Korean Patent Laid-open Publication No. 10-2010-0110459

### SUMMARY OF THE INVENTION

The present invention has been invented in order to overcome the above-described problems and it is, therefore, an object of the present invention to provide a method of manufacturing a printed circuit board that can improve a process yield by processing a via hole and forming a circuit layer in a state in which two copper clad laminates are bonded to each other.

In accordance with one aspect of the present invention to achieve the object, there is provided a method of manufacturing a printed circuit board, including the steps of: (a) preparing two copper clad laminates, each consisting of an insulating layer and copper foil layers laminated on upper and lower surfaces of the insulating layer; (b) bonding the two copper clad laminates after disposing the lower copper foil layers of the copper clad laminates to face each other; (c) processing a via hole passing through the upper copper foil layer and the insulating layer of each copper clad laminate; (d) fill-plating a via electrode inside the via hole and forming a circuit layer on an outer layer of the copper clad laminate; (e) separating the bonded copper clad laminates from each other; and (f) patterning the lower copper foil layer of the separated copper clad laminate.

Further, the formation of the circuit layer in the step (d) may use a subtractive method, an additive method, a semi-additive method, or a modified semi-additive (MSAP) method.

Further, in the step (b), the two copper clad laminates may be bonded by an adhesive member interposed therebetween.

Further, the adhesive member may be disposed on an edge of the copper clad laminate.

Further, the step (f) may consist of the steps of closely adhering a dry film to a surface of the lower copper foil layer; forming a pattern on the dry film through exposure and development; and etching a portion exposed by the pattern of the dry film and removing the dry film.

In accordance with another aspect of the present invention to achieve the object, there is provided a method of manufacturing a printed circuit board, including the steps of: (a) preparing two copper clad laminates, each consisting of an insulating layer and copper foil layers laminated on upper and lower surfaces of the insulating layer; (b) bonding the two copper clad laminates after disposing the lower copper foil layers of the copper clad laminates to face each other; (c) processing a via hole passing through the upper foil layer and the insulating layer of each copper clad laminate; (d) plating a metal layer on a surface of the upper copper foil layer of each copper clad laminate including the inside of the via hole; (e) separating the bonded copper clad laminates from each other; and (f) patterning both surfaces of the separated copper clad laminate.

Further, the step (d) may consist of the steps of forming a seed layer on the surface of the upper copper foil layer including an inner wall of the via hole; and performing electroplating using the seed layer as a lead-in wire.

Further, the step (f) may consist of the steps of closely adhering a dry film to the both surfaces of the copper clad laminate; forming a pattern on the dry film through exposure and development; and etching a portion exposed by the pattern of the dry film and removing the dry film.

In accordance with still another aspect of the present invention to achieve the object, there is provided a method of manufacturing a printed circuit board using a roll-to-roll method, including the steps of: bonding copper clad laminates to both surfaces of an adhesive member unwound from a first main unwinding roll through first roller means, which are respectively positioned on upper and lower surface sides of the adhesive member, and rewinding an upper and lower copper clad laminate around a first main winding roll; unwinding the upper and lower copper clad laminate wound around the first main winding roll to mount a certain amount of the upper and lower copper clad laminate on a flat table and performing drilling on the mounted upper and lower copper clad laminate to process a via hole; plating a metal layer on a surface of the upper and lower copper clad laminate while transferring the upper and lower copper clad laminate having the via hole in a roll-to-roll manner; separating the upper and lower copper clad laminate unwound from a second main unwinding roll through third roller means, which are respectively positioned on upper and lower surface sides of the upper and lower copper clad laminate, into the upper copper clad laminate and the lower copper clad laminate and rewinding the adhesive member around a second main winding roll; and forming circuit layers on both surfaces of the separated copper clad laminate.

Further, the first roller means may consist of a first roller wound with the copper clad laminate and a second roller for bonding the copper clad laminate unwound from the first roller to the surface of the adhesive member.

Further, the second roller means between the first main unwinding roll and the first roller means may be provided on the upper and lower surface sides of the adhesive member to remove protection films attached to the both surfaces of the adhesive member unwound from the first main unwinding roll.

First, the second roller means may consist of a first roller for stripping the protection film and a second roller for collecting the stripped protection film.

Further, the third roller means may consist of a first roller for separating the copper clad laminate from the adhesive member and a second roller for collecting the separated copper clad laminate.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1 to 7 are views sequentially showing a method of manufacturing a printed circuit board of the present invention;

FIGS. 8 to 11 are views sequentially showing a method of manufacturing a printed circuit board in accordance with another embodiment of the present invention; and

FIGS. 12 and 13 are views sequentially showing a method of manufacturing a printed circuit board using a roll-to-roll process.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The exemplary embodiments are provided only for completing the disclosure of the present invention and for fully representing the scope of the present invention to those skilled in the art. Like reference numerals refer to like elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

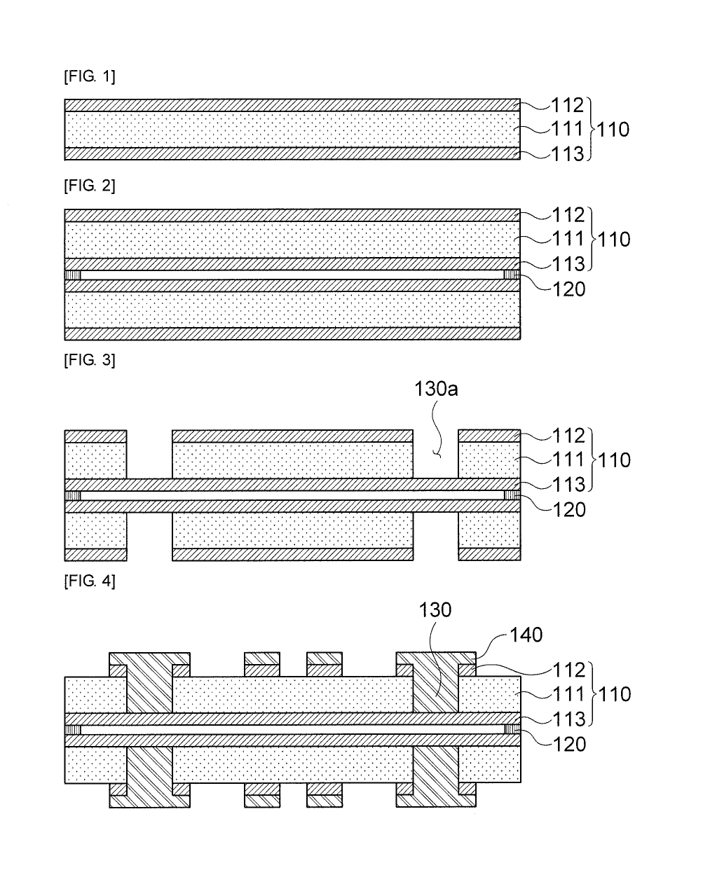

FIGS. 1 to 7 are views sequentially showing a method of manufacturing a printed circuit board of the present invention.

A method of manufacturing a printed circuit board, as in FIG. 1, first, prepares two copper clad laminates (CCL) 110, each of which consists of an insulating layer 111 and upper and lower copper foil layers 112 and 113 laminated on upper and lower surfaces of the insulating layer 111.

The insulating layer 111 may be prepreg or an Ajinmoto build-up film (ABF) which is a common insulating material. Further, in order to reinforce mechanical strength, a reinforcing material such as paper, glass cloth, or glass non-woven fabric may be added to the insulating layer 111.

For example, when manufacturing the CCL 110 using prepreg, the CCL 110 may be manufactured by laminating one or a plurality of sheets of prepreg, laminating copper foils on upper and lower surfaces of the prepreg, and hot-press molding the copper foils and the prepreg to integrate them.

Next, as in FIG. 2, the two CCLs 110 are bonded after disposing the lower copper foil layers 113 of the CCLs 110 to face each other. At this time, the CCLs 110 may be bonded to each other by an adhesive member 120 interposed therebetween.

The adhesive member 120 is a fluid material having adhesive properties. As an example, the adhesive member 120 may include one or more selected from the group consisting of epoxy resins, acrylic resins, polyester resins, and polyurethane resins.

In addition, for a subsequent separation process, the adhesive member 120 may additionally include a material that can be cured by an electron beam. Specifically, the adhesive member 120 may include a photopolymer cured by an electron beam.

Meanwhile, as shown in FIG. 2, the adhesive member 120 in the embodiment of the present invention may be disposed along an edge portion of the CCL 110. In this case, the adhesive member 120 can be easily stripped in the subsequent separation process. Further, since a residue of the adhesive member 120 doesn't exist on a surface of the lower copper foil layer 113 except the edge portion, it is possible to safely perform a subsequent process.

When the two CCLs 110 are bonded to each other, as in FIG. 3, a via hole 130a, which passes through the upper copper foil layer 112 and the insulating layer 111 of each CCL 110, is processed.

The via hole 130a may be formed through mechanical drilling using a drill bit or by removing the upper copper foil layer 112 in a portion in which the via hole 130a is to be formed to form an opening and removing the insulating layer exposed through the opening by etching or a CO2 laser drill. After processing the via hole 130a, it is preferred to perform deburring and desmearing for removing various contaminants and foreign materials stuck to an inner wall of the via hole 130a.

Next, as in FIG. 4, a via electrode 130 is fill-plated inside the via hole 130a, and a circuit layer 140 is formed on an outer layer of the CCL 110. As a pretreatment process for forming the circuit layer 140, a seed layer (not shown in the drawing) is plated on the inner wall of the via hole 130a and a surface of the upper copper foil layer 112 through deposition etc., and a metal layer is formed by performing electroplating using the seed layer as a lead-in wire.

At this time, the via electrode 130 is formed together when the inside of the via hole 130a is fill-plated. After that, the circuit layer is formed by selectively etching the metal layer using a generally known subtractive, additive, semi-additive, or modified semi-additive (MSAP) method. At this time, the upper copper foil layer 112 under the metal layer is patterned together.

Next, as in FIG. 5, the bonded CCLs 110 are separated from each other. It may be performed by irradiating an electron beam above the bonded CCLs 110. Since an electron beam has strong transmittance, it can easily reach the adhesive member 120.

When an electron beam is irradiated to the adhesive member 120, a resin included in the adhesive member 120 is cured through cross-linking etc. Through this, the adhesive properties of the adhesive member 120 disappear and thus the adhesive member 120 is easily stripped from the CCLs 110. Accordingly, the two CCLs 110 can be separated from each other.

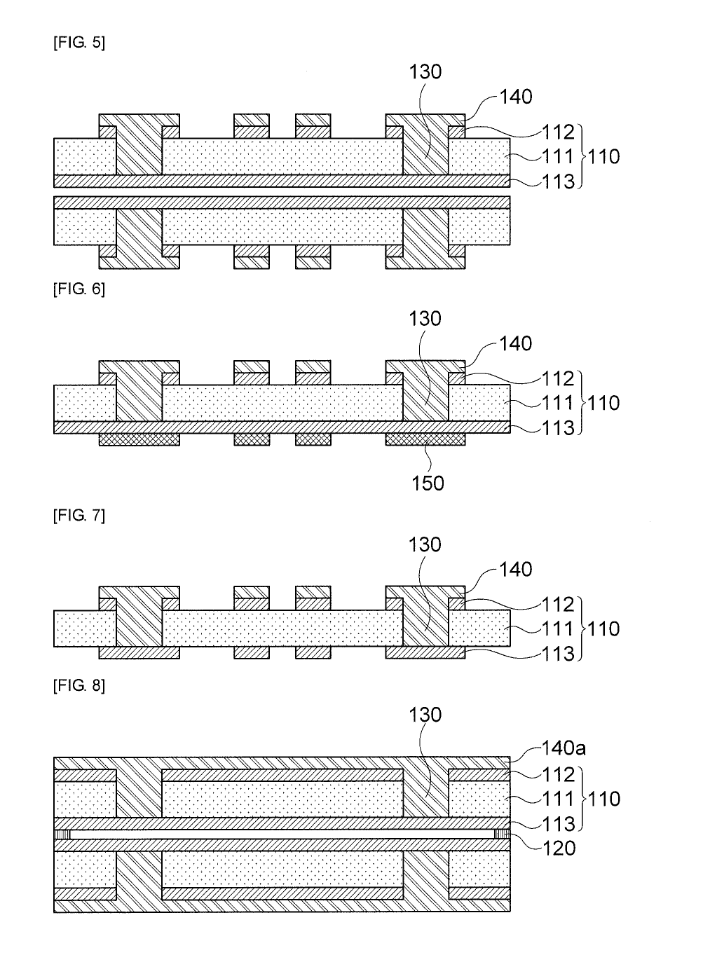

Next, the lower copper foil layer 113 of the separated CCL 110 is patterned. That is, the lower copper foil layer 113 is used as it is to form a circuit layer. First, as in FIG. 6, a dry film 150 is closely adhered to the surface of the lower copper foil layer 113. The dry film 150 is a photosensitive film. When an ultraviolet ray is selectively irradiated (exposed) in a state in which the dry film 150 is closely adhered, the irradiated portion is cured. After that, when the uncured portion is removed through a developing process, a predetermined pattern is formed on the dry film 150.

Next, the lower copper foil layer 113 exposed by the pattern of the dry film 150 is etched. Finally, when the dry film 150 is removed by a stripping solution (sodium hydroxide or potassium hydroxide), as in FIG. 7, a finally completed printed circuit board can be obtained.

Like this, the method of manufacturing a printed circuit board of the present invention can manufacture a plurality of printed circuit boards simply than a conventional method requiring a build-up process by proceeding a process using the two CCLs in which the copper foil layers are laminated on the both surfaces of the insulating layer from the beginning and directly patterning the separated surface (lower copper foil layer) later.

And, it is possible to reduce manufacturing costs by proceeding a process in a state in which the two CCLs are bonded without a separate dummy carrier.

And, it is possible to easily implement miniaturization of a printed circuit board by forming the circuit layer on one surface of the printed circuit board only with the copper foil of the CCL.

Now, a method of manufacturing a printed circuit board in accordance with another embodiment of the present invention will be described.

A method of manufacturing a printed circuit board in accordance with another embodiment of the present invention, like FIG. 1, first, prepares two CCLs 110, each of which consists of an insulating layer 111 and copper foil layers 112 and 113 laminated on upper and lower surfaces of the insulating layer 111.

Next, like FIG. 2, the two CCLs 110 are bonded after disposing the lower copper foil layers 113 of the CCLs 110 to face each other.

Next, like FIG. 3, a via hole 130a, which passes through the upper copper foil layer 112 and the insulating layer 111 of each CCL 110, is processed.

Next, as in FIG. 8, a metal layer 140a is plated on a surface of the upper copper foil layer 112 of each CCL 110 while filling the inside of the via hole 130a.

For this, first, a seed layer (not shown in the drawing) is formed on the surface of the upper copper foil layer 112 including an inner wall of the via hole 130a by performing electroless plating as a pretreatment process of electroplating. For example, the seed layer may be formed by sputtering metal deposition. When the seed layer is formed, electroplating is performed using the seed layer as a lead-in wire.

Electroplating is a method of depositing a metal by dipping the CCL 10 in a plating bath and applying an appropriate current to a DC rectifier according to an area to be plated. Through this, it is possible to form the metal layer 140a with a predetermined thickness on the surface of the upper copper foil layer 112 and fill-plate the inside of the via hole 130a at the same time. At this time, for example, the metal layer 140a may be made of an electrically conductive metal such as gold, silver, copper, or nickel.

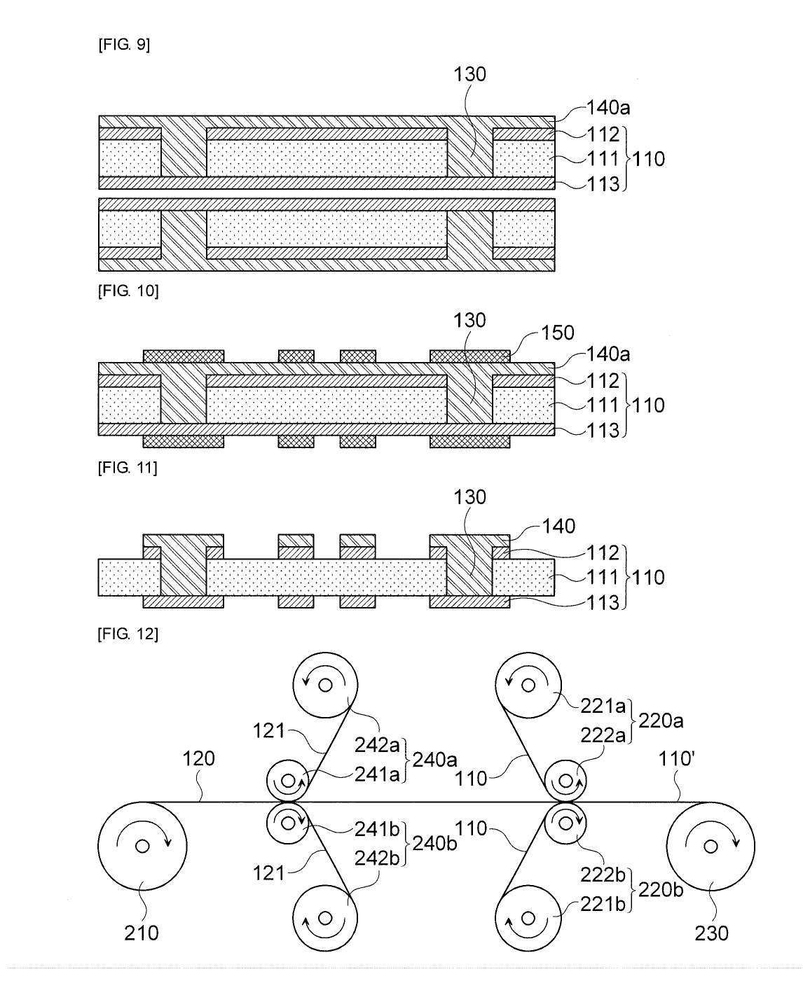

When the metal layer 140a is formed, as in FIG. 9, the bonded CCLs 110 are separated from each other, and both surfaces of the separated CCL 110 are patterned. This may be performed in the same way as the process of patterning the lower copper coil layer 113 in FIGS. 6 and 7.

That is, a circuit layer 140 of a predetermined pattern can be formed as in FIG. 11 by closely adhering a dry film 150 having a predetermined pattern to the metal layer 140a as in FIG. 10 and etching the metal layer 140a exposed by the pattern of the dry film 150 together with the upper copper coil layer 112 under the metal layer 140a. Similarly, a predetermined pattern may be formed in the same way after closely adhering the dry film 150 to the lower copper foil layer 113.

Like this, in the method of manufacturing a printed circuit board in accordance with another embodiment of the present invention, it is possible to more efficiently proceed a process by separating the two bonded CCLs and performing patterning on the both surfaces of the separated CCL 110 at the same time.

Now, a method of manufacturing a printed circuit board of the present invention using a roll-to-roll process will be described. In the roll-to-roll method, the point of the present invention is a process of bonding CCLs 110 to both surfaces of an adhesive member 120 and a subsequent process of separating the upper and lower CCLs bonded by the adhesive member 120. The well-known roll-to-roll method may be used in a process of processing a via hole, a plating process, and a process of forming a circuit layer.

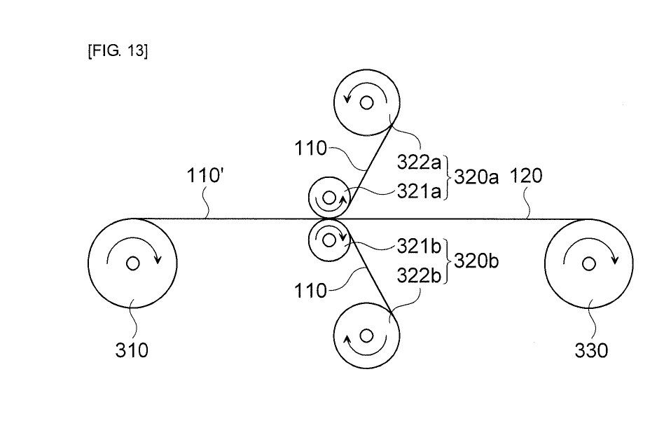

And, in FIGS. 12 and 13, a roll-to-roll process apparatus is highlighted. Therefore, hereinafter, reference numerals of components of a printed circuit board will refer to FIGS. 1 to 11.

A method of manufacturing a printed circuit board of the present invention using a roll-to-roll process, as in FIG. 12, first, bonds CCLs 110 to both surfaces of an adhesive member 120 through first roller means 220a and 220b, which are respectively positioned on upper and lower surface sides of the adhesive member 120 unwound from a main unwinding roll 210 and rewinds the adhesive member 120 around a first main winding roll 230.

More specifically, the first roller means 220a and 220b consist of first rollers 221a and 221b wound with the CCLs 110 and second rollers 222a and 222b for bonding the CCLs 110 unwound from the first rollers 221a and 221b to the surface of the adhesive member 120.

At this time, the second roller 222a on the upper surface side and the second roller 222b on the lower surface side are spaced apart from each other by a predetermined interval, and the both surfaces of the adhesive member 120 unwound from the first main unwinding roll 210 pass between the second rollers 222a and 222b while being in contact with roller surfaces of the second rollers 222a and 222b. Accordingly, the CCLs 110 unwound from the first rollers 221a and 221b are bonded to the both surfaces of the adhesive member 120 by the adhesive strength of the adhesive member 120. Hereinafter, the upper and lower CCLs bonded to each other with the adhesive member 120 therebetween will be simply referred to as an upper and lower CCL 110′.

Meanwhile, for protection of the adhesive member 120, protection films 121 may be attached to the both surfaces of the adhesive member 120 unwound from the main unwinding roll 210. Therefore, the second roller means 240a and 240b for stripping the protection films 210 before bonding the CCLs 110 may be positioned between the first main unwinding roll 210 and the second roller means 220a and 220b.

The second roller means 240a and 240b are respectively positioned on the upper and lower surface sides of the adhesive member 120, and each of the second roller means 240a and 240b consists of a first roller 241a and 241b for stripping the protection film 121 and a second roller 242a and 242b for collecting the stripped protection film 121.

At this time, the first roller 241a on the upper surface side and the first roller 241b on the lower surface side are spaced apart from each other by a predetermined interval, and the both surfaces of the adhesive member 120 unwound from the first main unwinding roll 210 pass between the first rollers 241a and 241b while being in contact with roller surfaces of the first rollers 241a and 241b.

Since the interval between the first rollers 241a and 241b is smaller than a thickness of the adhesive member 120, when the adhesive member 120 passes between the first rollers 241a and 241b, the protection films 121 are stripped from the adhesive member 120 by the pressure applied from the first rollers 241a and 241b and the rotary power of the first rollers 241a and 241b and wound around the second rollers 242a and 242b.

When the upper and lower CCL 110′ is wound around the first main winding roll 230, the upper and lower CCL 110′ is rewound and transferred onto a flat table. When a certain amount of the upper and lower CCL 110′ is transferred to the flat table, the roller stops driving to mount the upper and lower CCL 110′ on the flat table, and a via hole 130a is processed by performing drilling on a surface of the mounted upper and lower CCL 110′. At this time, drilling is performed on both sides of the upper and lower CCL 110′, and only an upper copper foil layer 112 and an insulating layer 111 of each CCL 110 are processed.

Next, the CCL 110 having the via hole 130a is continuously supplied to a deposition region prepared in a vacuum chamber in a roll-to-roll manner and a metal layer 140a is plated on a surface of the upper copper coil layer 112 including an inner wall of the via hole 130a.

Next, the step of separating the upper and lower CCL 110′ is performed. For this, as in FIG. 13, the upper and lower CCL 110′ is wound around a second main unwinding roll 310, and the second main unwinding roll 310 is rotated at a predetermined speed to unwind the upper and lower CCL 110′. The unwound upper and lower CCL 110′ is separated into the upper CCL 110 and the lower CCL 110 by third roller means 320a and 320b, which are respectively positioned on the upper and lower surface sides of the upper and lower CCL 110′, and the adhesive member 120 is wound around a second main winding roll 330.

More specifically, the third roller means 320a and 320b consist of first rollers 321a and 321b for stripping the CCLs 110 from the adhesive member 120 and second rollers 322a and 322b for collecting the stripped CCLs 110.

Here, the first roller 321a on the upper surface side and the first roller 321b on the lower surface side are spaced apart from each other by a predetermined interval, and the upper and lower CCL 110′ passes between the first rollers 321a and 321b while being in contact with roller surfaces of the first rollers 321a and 321b. At this time, since the interval between the first rollers 321a and 321b is smaller than a thickness of the upper and lower CCL 110′, when the upper and lower CCL 110′ passes between the first rollers 321a and 321b, the adhesive strength of the adhesive member 120 is deteriorated due to the pressure applied from the first rollers 321a and 321b and the rotary power of the first rollers 321a and 321b so that each CCL 110 is separated from the adhesive member 120. The separated CCLs 110 are wound around the second rollers 322a and 322b, and the adhesive member 120 is wound around the second main winding roll 330.

After that, the separated CCLs 110 are transferred in a roll-to-roll manner, and circuit layers are formed on the both surfaces of the CCL through an etching process.

According to the method of manufacturing a printed circuit board of the present invention, it is possible to manufacture a plurality of printed circuit boards simply than a conventional method requiring a build-up process by proceeding a process using the two CCLs in which the copper foil layers are laminated on the both surfaces of the insulating layer from the beginning and directly patterning the separated surface (lower copper foil layer) later.

And, it is possible to reduce manufacturing costs by proceeding a process in a state in which the two CCLs are bonded without a separate dummy carrier.

And, it is possible to easily implement miniaturization of a printed circuit board by forming the circuit layer on one surface of the printed circuit board only with the copper foil of the CCL.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

1. A method of manufacturing a printed circuit board, comprising:
preparing two copper clad laminates, each including an insulating layer and copper foil layers laminated on upper and lower surfaces of the insulating layer;
bonding the two copper clad laminates after disposing the lower copper foil layers of the copper clad laminates to face each other;
processing a via hole passing through the upper copper foil layer and the insulating layer of each copper clad laminate;
fill-plating a via electrode inside the via hole and forming a circuit layer on an outer layer of the copper clad laminate;
separating the bonded copper clad laminates from each other; and
patterning the lower copper foil layer of the separated copper clad laminate.

2. The method of manufacturing a printed circuit board according to claim 1, wherein in the bonding, the two copper clad laminates are bonded by an adhesive member interposed therebetween.

3. The method of manufacturing a printed circuit board according to claim 2, wherein the adhesive member is disposed on an edge of the copper clad laminate.

4. The method of manufacturing a printed circuit board according to claim 1, wherein the formation of the circuit layer in the fill-plating uses a subtractive method, an additive method, a semi-additive method, or a modified semi-additive (MSAP) method.

5. The method of manufacturing a printed circuit board according to claim 1, wherein the patterning comprises:
closely adhering a dry film to a surface of the lower copper foil layer;
forming a pattern on the dry film through exposure and development; and
etching a portion exposed by the pattern of the dry film and removing the dry film.

6. A method of manufacturing a printed circuit board, comprising:
preparing two copper clad laminates, each including an insulating layer and copper foil layers laminated on upper and lower surfaces of the insulating layer;
bonding the two copper clad laminates after disposing the lower copper foil layers of the copper clad laminates to face each other;
processing a via hole passing through the upper foil layer and the insulating layer of each copper clad laminate;
plating a metal layer on a surface of the upper copper foil layer of each copper clad laminate including the inside of the via hole;
separating the bonded copper clad laminates from each other; and
patterning both surfaces of the separated copper clad laminate.

7. The method of manufacturing a printed circuit board according to claim 6, wherein the plating comprises:
forming a seed layer on the surface of the upper copper foil layer including an inner wall of the via hole; and
performing electroplating using the seed layer as a lead-in wire.

8. The method of manufacturing a printed circuit board according to claim 6, wherein the patterning comprises:
closely adhering dry films to the both surfaces of the copper clad laminate;
forming a pattern on the dry film through exposure and development; and
etching a portion exposed by the pattern of the dry film and removing the dry film.

9. A method of manufacturing a printed circuit board using a roll-to-roll method, comprising:
bonding copper clad laminates to both surfaces of an adhesive member unwound from a first main unwinding roll through first roller means, which are respectively positioned on upper and lower surface sides of the adhesive member, and rewinding an upper and lower copper clad laminate around a first main winding roll;
unwinding the upper and lower copper clad laminate wound around the first main winding roll to mount a certain amount of the upper and lower copper clad laminate on a flat table and performing drilling on the mounted upper and lower copper clad laminate to process a via hole;
plating a metal layer on a surface of the upper and lower copper clad laminate while transferring the upper and lower copper clad laminate having the via hole in a roll-to-roll manner;
separating the upper and lower copper clad laminate unwound from a second main unwinding roll through third roller means, which are respectively positioned on upper and lower surface sides of the upper and lower copper clad laminate, into the upper copper clad laminate and the lower copper clad laminate and rewinding the adhesive member around a second main winding roll; and
forming circuit layers on both surfaces of the separated copper clad laminate.

10. The method of manufacturing a printed circuit board using a roll-to-roll method according to claim 9, wherein the first roller includes a first roller wound with the copper clad laminate and a second roller for bonding the copper clad laminate unwound from the first roller to the surface of the adhesive member.

11. The method of manufacturing a printed circuit board using a roll-to-roll method according to claim 9, wherein the second roller between the first main unwinding roll and the first roller means are respectively provided on the upper and lower surface sides of the adhesive member to remove protection films attached to the both surfaces of the adhesive member unwound from the first main unwinding roll.

12. The method of manufacturing a printed circuit board using a roll-to-roll method according to claim 11, wherein the second roller includes a first roller for stripping the protection film and a second roller for collecting the stripped protection film.

13. The method of manufacturing a printed circuit board using a roll-to-roll method according to claim 9, wherein the third roller includes a first roller for separating the copper clad laminate from the adhesive member and a second roller for collecting the separated copper clad laminate.
